(19) United States
(12) Patent Application Publication
(10) Pub. No.: US 2022/0349049 A1
(43) Pub. Date: Nov. 3, 2022

(54) COMPOSITIONS AND METHODS USING SAME FOR DEPOSITION OF SILICON-CONTAINING FILM

(71) Applicant: VERSUM MATERIALS US, LLC, TEMPLE, AZ (US)

(72) Inventors: RAYMOND N. VRTIS, CARLSBAD, CA (US); ROBERT G. RIDGEWAY, CHANDLER, AZ (US)

(73) Assignee: VERSUM MATERIALS US, LLC, TEMPE, AZ (US)

(21) Appl. No.: 17/621,198

(22) PCT Filed: Jun. 19, 2020
(86) PCT No.: PCT/US20/38588

§ 371 Date: Dec. 20, 2021

Related U.S. Application Data
(60) Provisional application No. 62/864,693, filed on Jun. 21, 2019.

(51) Int. Cl. C23C 16/36; C23C 16/511; C23C 16/56; C23C 16/455; H01L 21/02

(52) U.S. Cl. CPC C23C 16/36; C23C 16/511; C23C 16/56; C23C 16/45565; H01L 21/02164; H01L 21/02167; H01L 21/0214; H01L 21/02211; H01L 21/02274

(57) ABSTRACT

Compositions and methods using same are used for forming a silicon-containing film such as without limitation a silicon carbide, silicon oxynitride, a carbon-doped silicon nitride, a carbon-doped silicon oxide, or a carbon doped silicon oxynitride film on at least a surface of a substrate having a surface feature. The silicon-containing film is deposited using an alkylhydridosilane compound containing at least one Si—H bond.

### CROSS-REFERENCE TO RELATED APPLICATIONS

This application is a National Stage filing under 35 U.S.C. 371 of International Patent Application No. PCT/US2020/038588 filed Jun. 19, 2020, which claims priority to Provisional U.S. Application No. 62/864,693, filed Jun. 21, 2019. The entire contents of these applications are incorporated herein by reference in their entirety.

### FIELD OF THE INVENTION

Described herein is a process for the fabrication of an electronic device. More specifically, described herein are compositions for forming a silicon-containing film in a deposition process, such as, without limitation, a flowable chemical vapor deposition. Exemplary silicon-containing films that can be deposited using the compositions and methods described herein include, without limitation, silicon carbide, silicon oxynitride, carbon-doped silicon oxide or carbon-doped silicon nitride films.

### BACKGROUND OF THE INVENTION

US Publ. No. 2013/0217241 discloses the deposition and treatment of Si—C—N containing flowable layers. Si and C may come from a Si—C-containing precursor, while N may come from an N-containing precursor. The initial Si—C—N containing flowable layer is treated to remove components that enables the flowability. Removal of these components can increase etch tolerance, reduce shrinkage, adjust film tension and electrical properties. The post treatment can be thermal annealing, UV exposure or high density plasma.

U.S. Pat. No. 8,889,566 discloses a method to deposit flowable film by exciting the silicon precursor with a local plasma and depositing with a second plasma. The silicon precursor can be silylamine, higher order silane or halogenated silane. The second reactant gas can be NH₃, N₂, H₂, and/or O₂.

U.S. Pat. No. 7,825,040 discloses a method of filling a gap by introducing an alkoxysilane or aminosilane precursor, and depositing a flowable Si-containing film by plasma reaction. The precursor does not include a Si—C bond or a C—C bond.

U.S. Pat. Nos. 8,889,566, 7,521,378, and 8,575,040 describe an approach to depositing a silicon oxide film using a flowable chemical vapor deposition process to accomplish gas phase polymerization. Compounds such as trisilylamine (TSA) were used to deposit Si, H, and N containing oligomers that were subsequently oxidized to SiOₓ films using ozone exposure.

U.S. Pat. No. 8,846,536 discloses a method to deposit and modify the flowable dielectric film. By one or more integration processes, the wet etch rate of the flowable dielectric film can be changed by a factor of at least 10.

The disclosure of the previously identified patents and patent applications is hereby incorporated by reference.

Despite the recent activity in the art related to flowable chemical vapor deposition and other film deposition processes, problems still remain. One of these problems is related to film stress and voiding. Flowable films are mostly deposited at a lower temperature, although the high temperature and high energy post treatment leads to high film stress and creates voids in the features. Lowering the wet etch rate has been challenging due to the low film quality at low process temperature. Thus there is a need to provide alternative precursor compounds, precursor combinations, or modified techniques, or a combination thereof.

### BRIEF SUMMARY OF THE INVENTION

The compositions or formulations described herein and methods using same overcome the problems of the prior art by depositing a silicon-containing film on at least a portion of the substrate surface that provides desirable film properties upon post-deposition treatment. The inventive compositions and methods can provide a silicon-containing film having the following characteristics: i) a film tensile stress, as measured using a Toho stress tool, ranging from about 10 to about 20 MPa after a thermal cure and ranging from about 150 to about 190 MPa after a UV cure, and ii) a density, as measured by X-Ray reflectance ranging from about 1.35 to about 2.10 g/cm³. The as-deposited films are flowable and able to fill features which are less than 50 nm wide and having aspect ratios of 2:1 or greater and can be completely annealed using an energy source such as but not limited to thermal, UV light or electron beam. The annealing film is stable to air and does not result in voiding within the features.

The silicon-containing film is selected from the group consisting of a silicon carbide, a silicon oxide, a carbon-doped silicon nitride, and a carbon-doped silicon oxynitride film. In certain embodiments, the substrate comprises a surface feature. The term “surface feature,” as used herein, means that the substrate or partially fabricated substrate that comprises one or more of the following: pores, trenches, shallow trench isolation (STI), vias, reentrant feature, and the like. The compositions can be pre-mixed compositions, pre-mixtures (mixed before being used in the deposition process), or in-situ mixtures (mixed during the deposition process). Thus, in this disclosure the terms “mixture,” “formulation,” and “composition” are interchangeable.

In one aspect, there is provided a method for depositing a silicon-containing film, the method comprising:
placing a substrate comprising a surface feature into a reactor which is at one or more temperatures ranging from −20° C. to about 200° C.;
introducing into the reactor a compound having at least one silicon-hydrogen bond and having the formula RₙSiH₄₋ₙ wherein R is independently selected from a linear or branched C₂ to C₆ alkyl or a C₆-C₁₀ aryl group and n is a number selected from 1, 2, 3; and
providing a plasma source into the reactor to at least partially react the compound to form a flowable liquid or oligomer wherein the flowable liquid or oligomer at least partially fills a portion of the surface feature.

In one particular embodiment, the plasma source is selected from the group consisting of a nitrogen plasma; plasma comprising nitrogen and helium; a plasma comprising nitrogen and argon; an ammonia plasma; a plasma comprising ammonia and helium; a plasma comprising ammonia and argon; helium plasma; argon plasma; hydrogen plasma; a plasma comprising hydrogen and helium; a plasma comprising hydrogen and argon; a plasma comprising ammonia and hydrogen; an organic amine plasma; a plasma comprising oxygen; a plasma comprising oxygen and hydrogen, and mixtures thereof.

In another embodiment, the plasma source is selected from the group consisting of a carbon source plasma, including a hydrocarbon plasma, a plasma comprising hydrocarbon and helium, a plasma comprising hydrocarbon and argon, carbon dioxide plasma, carbon monoxide plasma, a plasma comprising hydrocarbon and hydrogen, a plasma comprising hydrocarbon and a nitrogen source, a plasma comprising hydrocarbon and an oxygen source, and mixture thereof.

The plasma source may be in-situ or may be a remote source such as a remote microwave or remote plasma source.

In any of the above or in an alternative embodiment, the method further includes subjecting the deposited flowable liquid or oligomer to a thermal treatment at one or more temperatures ranging from about 100° C. to about 1000° C. to densify at least a portion of the deposited materials.

According to another exemplary embodiment, the post thermal treatment materials are exposed to a plasma, infrared lights, chemical treatment, an electron beam, or UV light to form a dense film.

Some or all of the above steps define one cycle, and the cycle can be repeated until a desired thickness of a silicon-containing film is obtained. In this or other embodiments, it is understood that the steps of the methods described herein may be performed in a variety of orders, may be performed sequentially or concurrently (e.g., during at least a portion of another step), and any combination thereof. The respective step of supplying the compounds and other reagents may be performed by varying the duration of the time for supplying them to change the stoichiometric composition of the resulting silicon-containing film.

Another embodiment of the invention relates to a film formed by the inventive method as well as a film having the previously identified characteristics.

The various embodiments of the invention can be used alone or in combinations with each other.

### BRIEF DESCRIPTION OF SEVERAL VIEWS OF THE DRAWINGS

FIG. 1 is a cross-sectional SEM image of an organosilicate glass (OSG) film formed by flowable CVD using triethylsilane (3ES) as a precursor, the film exhibiting seamless and void-free gap-fill.

### DETAILED DESCRIPTION OF THE INVENTION

Described herein are methods employing an alkylhydridosilane compound to deposit a flowable film via a chemical vapor deposition (CVD) process on at least a portion of a substrate having a surface feature. As discussed previously, films deposited by flowable CVD are often susceptible to film shrinkage during post-treatment due to the low process temperature. Voids and seams can form in such films due to significant film shrinkage and an increase of film stress. Thus, it has been challenging to densify the film without increasing film stress or creating voids. The method described herein overcomes these problems by improving the fill of at least a portion of a surface feature on a substrate.

The method is performed using alkylhydridosilane precursor compounds having the formula RₙSiH₄₋ₙ wherein R is independently selected from a linear or branched C₂ to C₆ alkyl or a C₆-C₁₀ aryl group and n is a number selected from 1, 2, 3. Exemplary precursor compounds include, but are not limited to ethylsilane, diethylsilane, triethylsilane, isopropyldiethylsilane, phenyldiethylsilane, and benzyldiethylsilane.

In the formulae above and throughout the description, the term “linear or branched alkyl” denotes a linear functional group having from 2 to 6, carbon atoms. Exemplary linear or branched alkyl groups include, but are not limited to, ethyl (Et), isopropyl (Prⁱ), isobutyl (Buⁱ), sec-butyl (Bu^{s}), tert-butyl (Bu^{t}), iso-pentyl, tert-pentyl (am), isohexyl, and neohexyl. In certain embodiments, the alkyl group may have one or more functional groups such as, but not limited to, an alkoxy group, a dialkylamino group or combinations thereof, attached thereto. In other embodiments, the alkyl group does not have one or more functional groups attached thereto. The alkyl group may be saturated or, alternatively, unsaturated.

In the formulae above and throughout the description, the term “cyclic alkyl” denotes a cyclic group having from 3 to 10 atoms. Exemplary cyclic alkyl groups include, but are not limited to, cyclobutyl, cyclopentyl, cyclohexyl, and cyclooctyl groups. In certain embodiments, the cyclic alkyl group has from 3 to 10 atoms linear or branched substituents, or substituents containing oxygen or nitrogen atoms. The cyclic alkyl group may have one or more linear or branched alkyl or alkoxy groups as substituents, such as, for example, a methylcyclohexyl group or a methoxycyclohexyl group.

In the formulae above and throughout the description, the term “aryl group” denotes a group having from 3 to 10 atoms. Exemplary aryl groups include, but are not limited to, methylbenzene, benzyl, and phenol.

In certain embodiments, one or more of the alkyl group in the formulae may be “substituted” or have one or more atoms or group of atoms substituted in place of, for example, a hydrogen atom. Exemplary substituents include, but are not limited to, oxygen, sulfur, halogen atoms (e.g., F, Cl, I, or Br), nitrogen, alkyl groups, and phosphorous

The silicon precursor compounds described herein may be delivered to the reaction chamber such as a CVD or ALD reactor in a variety of ways. In one embodiment, a liquid delivery system is utilized. In an alternative embodiment, a combined liquid delivery and flash vaporization process unit are employed, such as, for example, the turbo vaporizer manufactured by MSP Corporation of Shoreview, Minn., to enable low volatility materials to be volumetrically delivered, which leads to reproducible transport and deposition without thermal decomposition of the precursor. In liquid delivery formulations, the precursors described herein may be delivered in neat liquid form, or alternatively, may be employed in solvent formulations or compositions comprising same. Thus, in certain embodiments the precursor formulations include solvent component(s) of suitable character as may be desirable and advantageous in a given end use application to form a film on a substrate. Examples of suitable solvents include at least one member selected from the group consisting of non-polar alkane based solvents such as cyclohexane and cyclohexanone.

The silicon precursor compounds are preferably substantially free of halide ions such as chloride or metal ions such as Al. As used herein, the term “substantially free” as it relates to halide ions (or halides) such as, for example, chlorides and fluorides, bromides, iodides, Al³⁺ ions, Fe²⁺, Fe³⁺, Ni²⁺, Cr³⁺ means less than 5 ppm (by weight), preferably less than 3 ppm, and more preferably less than 1 ppm, and most preferably 0 ppm. Chlorides or metal ions are known to act as decomposition catalysts for silicon precursors. Significant levels of chloride in the final product can cause the silicon precursors to degrade. The gradual degradation of the silicon precursors may directly impact the film deposition process making it difficult for the semiconductor manufacturer to meet film specifications. In addition, the precursor shelf-life or stability is negatively impacted by the higher degradation rate of the silicon precursors thereby making it difficult to guarantee a 1-2 year shelf-life.

The method used to form the films or coatings described herein are flowable chemical vapor deposition processes. Examples of suitable deposition processes for the method disclosed herein include, but are not limited to, cyclic flowable chemical vapor deposition (CFCVD), or plasma enhanced flowable chemical vapor deposition (PEFCVD), remote activated chemical vapor deposition (RACVD). As used herein, the term “flowable chemical vapor deposition processes” refers to any process wherein a substrate is exposed to one or more volatile precursors, which react and/or decompose above the substrate surface or on the substrate surface to provide flowable oligomeric silicon-containing species which are flowable and then produce the solid film or material upon further treatment and, in some cases, at least a portion of the oligomeric species comprises polymeric species. Although the precursors, reagents and sources used herein may be sometimes described as “gaseous,” it is understood that the precursors can be either liquid or solid which are transported with or without an inert gas into the reactor via direct vaporization, bubbling or sublimation. In some cases, the vaporized precursors pass through a plasma generator. In one embodiment, the films are deposited using a plasma-based (e.g., remote generated or in situ) CVD process. The term “reactor” as used herein, includes without limitation, a reaction chamber or deposition chamber.

The precursor compounds described herein may be delivered to the flowable chemical vapor deposition reactor in a variety of ways including but not limited to vapor draw, bubbling or direct liquid injection (DLI). In one embodiment, a liquid delivery system may be utilized. In another embodiment, reactor may be equipped with a dual plenum showerhead to keep the plasma species generated remotely separate from vapors of the precursors until they are combined in the reactor to deposit flowable liquid. In an alternative embodiment, a combined liquid delivery and flash vaporization process unit may be employed, such as, for example, the turbo vaporizer manufactured by MSP Corporation of Shoreview, Minn., to enable low volatility materials to be volumetrically delivered, which leads to reproducible transport and deposition without thermal decomposition of the precursor. In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

In certain embodiments, the substrate may be exposed to one or more pre-deposition treatments such as, but not limited to, a plasma treatment, thermal treatment, chemical treatment, ultraviolet light exposure, electron beam exposure, and combinations thereof to affect one or more properties of the films. These pre-deposition treatments may occur under an atmosphere selected from inert, oxidizing, and/or reducing.

Energy is applied to the at least one of the precursor compound, nitrogen-containing source, oxygen source, hydrogen source, other precursors or combinations thereof to induce reaction and to form the silicon-containing film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively a remote plasma-generated process in which plasma is generated outside of the reactor and supplied into the reactor.

As previously mentioned, the method deposits a film upon at least a portion of the surface of a substrate comprising a surface feature. The substrate is placed into the reactor and the substrate is maintained at one or more temperatures ranging from about −20° C. to about 200° C. In one particular embodiment, the temperature of the substrate is less than the walls of the chamber. In order to limit films shrinkage during curing it may be advantageous to deposit the flowable films at the highest temperature at which flowability is exhibited, preferably at temperatures below 150 C.

As previously mentioned, the substrate comprises one or more surface features. In one particular embodiment, the surface feature(s) have a width of 1 μm in width or less, or 500 nm in width or less, or 50 nm in width or less, or 10 nm in width. In this or other embodiments, the aspect ratio (the depth to width ratio) of the surface features, if present, is 0.1:1 or greater, or 1:1 or greater, or 10:1 or greater, or 20:1 or greater, or 40:1 or greater. The substrate may be a single crystal silicon wafer, a wafer of silicon carbide, a wafer of aluminum oxide (sapphire), a sheet of glass, a metallic foil, an organic polymer film or may be a polymeric, glass, silicon or metallic 3-dimensional article. The substrate may be coated with a variety of materials well known in the art including films of silicon oxide, silicon nitride, amorphous carbon, silicon oxycarbide, silicon oxynitride, silicon carbide, gallium arsenide, gallium nitride and the like. These coatings may completely coat the substrate, may be in multiple layers of various materials and may be partially etched to expose underlying layers of material. The surface may also have on it a photoresist material that has been exposed with a pattern and developed to partially coat the substrate.

In one aspect of the invention, the substrate comprises at least one member selected from the group consisting of Si, SiOₓ, SiN, SiGe, SiOC and SiON. In another aspect of the invention, the inventive silicon containing film can be employed as a hard mask and provide etch selectivity to a photoresist. In a further aspect of the invention, the inventive silicon containing film functions as a dielectric film between conductive materials, as a barrier between conductive and other dielectric, or as a film within a sandwich dielectric.

In certain embodiments, the reactor is at a pressure below atmospheric pressure or 750 torr or less, or 100 torr or less. In other embodiments, the pressure of the reactor is maintained at a range of about 0.1 torr to about 10 torr.

In one particular embodiment, the introducing step, wherein the at least one compound and a plasma are introduced into the reactor, is conducted at one or more temperatures ranging from about from −20 to about 200° C. In these or other embodiments, the substrate comprises a semiconductor substrate comprising a surface feature. The plasma comprising nitrogen can be selected from the group consisting of nitrogen plasma, nitrogen/hydrogen plasma, nitrogen/helium plasma, nitrogen/argon plasma, ammonia plasma, ammonia/helium plasma, ammonia/argon plasma, ammonia/nitrogen plasma, NF₃, NF₃ plasma, organic amine plasma, and mixtures thereof. The at least one compound and nitrogen source react and form a silicon nitride film (which is non-stoichiometric) or a silicon carbonitride film on at least a portion of the surface feature and substrate. The term “organic amine” as used herein describes an organic compound that has at least one nitrogen atom. Examples of organoamine, but are not limited to, methylamine, ethylamine, propylamine, iso-propylamine, tert-butylamine, sec-butylamine, tert-amylamine, ethylenediamine, dimethylamine, trimethylamine, diethylamine, pyrrole, 2,6-dimethylpiperidine, di-n-propylamine, di-iso-propylamine, ethylmethylamine, N-methylaniline, pyridine, and triethylamine.

In another embodiment, the plasma source is selected from but not limited to the group consisting of a carbon source plasma, including a hydrocarbon plasma, a plasma comprising hydrocarbon and helium, a plasma comprising hydrocarbon and argon, carbon dioxide plasma, carbon monoxide plasma, a plasma comprising hydrocarbon and hydrogen, a plasma comprising hydrocarbon and a nitrogen source, a plasma comprising hydrocarbon and an oxygen source, and mixture thereof. The at least one compound and carbon source react and form a silicon carbide film (which is non-stoichiometric), or a silicon carbonitride film, film on at least a portion of the surface feature and substrate.

In a different embodiment, the plasma source is selected from but not limited to hydrogen plasma, helium plasma, argon plasma, xenon plasma, and mixture thereof. The at least one compound and plasma react and form a silicon carbide film, or a silicon carbonitride film on at least a portion of the surface feature and substrate.

In certain embodiments, after the silicon containing film is deposited, the substrate is optionally treated with an oxygen-containing source under certain process conditions sufficient to make the silicon nitride film form a silicon oxide or a silicon oxynitride or to convert a silicon carbide film to a carbon doped silicon oxide film. The oxygen-containing source can be selected from the group consisting of water (H₂O), oxygen (O₂), oxygen plasma, ozone (O₃), NO, N₂O, carbon monoxide (CO), carbon dioxide (CO₂), N₂O plasma, carbon monoxide (CO) plasma, carbon dioxide (CO₂) plasma, and combinations thereof.

In certain embodiments, the flowable liquid or oligomer is treated at one or more temperatures ranging from about 100° C. to about 1000° C. to densify at least a portion of the materials.

In some embodiments, the post thermal treatment materials are exposed to a plasma, infrared lights, chemical treatment, an electron beam, or UV light to form a dense film.

The above steps define one cycle for the methods described herein; and the cycle can be repeated until the desired thickness of a silicon-containing film is obtained. In this or other embodiments, it is understood that the steps of the methods described herein may be performed in a variety of orders, may be performed sequentially or concurrently (e.g., during at least a portion of another step), and any combination thereof. The respective step of supplying the compounds and other reagents may be performed by varying the duration of the time for supplying them to change the stoichiometric composition of the resulting silicon-containing film.

In one aspect, there is provided a method for depositing a silicon-containing film, the method comprising:
placing a substrate comprising a surface feature into a reactor which is at one or more temperatures ranging from −20° C. to about 200° C.;
introducing into the reactor an alkylhydridosilane compound having at least one Si—H bond selected from the group consisting of the formula:
RₙSiH₄₋ₙ wherein R is independently selected from a linear or branched C₂ to C₆ alkyl or a C₆-C₁₀ aryl group and n is a number selected from 1, 2, and 3;
providing a plasma source into the reactor to at least partially react the first and second compounds to form a flowable liquid or oligomer wherein the flowable liquid or oligomer at least partially fills a portion of the surface feature. The above steps define one cycle for the methods described herein; and the cycle can be repeated until the desired thickness of a silicon-containing film is obtained. In this or other embodiments, it is understood that the steps of the methods described herein may be performed in a variety of orders, may be performed sequentially or concurrently (e.g., during at least a portion of another step), and any combination thereof. The respective step of supplying the compounds and other reagents may be performed by varying the duration of the time for supplying them to change the stoichiometric composition of the resulting silicon-containing film.

The plasma comprising nitrogen can be selected from the group consisting of nitrogen plasma, nitrogen/hydrogen plasma, nitrogen/helium plasma, nitrogen/argon plasma, ammonia plasma, ammonia/helium plasma, ammonia/argon plasma, ammonia/nitrogen plasma, organic amine plasma, and mixtures thereof.

In another embodiment, the plasma source is selected from but not limited to the group consisting of a carbon source plasma, including a hydrocarbon plasma, a plasma comprising hydrocarbon and helium, a plasma comprising hydrocarbon and argon, carbon dioxide plasma, carbon monoxide plasma, a plasma comprising hydrocarbon and hydrogen, a plasma comprising hydrocarbon and a nitrogen source, a plasma comprising hydrocarbon and an oxygen source, and mixture thereof.

In any of the above or in an alternative embodiment, the plasma source is selected from but not limited to hydrogen plasma, helium plasma, argon plasma, xenon plasma, and mixture thereof. The at least one compound and plasma react and form a silicon carbide film, film on at least a portion of the surface feature and substrate.

In certain embodiments, after the silicon containing film is deposited, the substrate is optionally treated with an oxygen-containing source under certain process conditions sufficient to make the silicon carbide or silicon carbonitride film form a silicon oxide or a silicon oxynitride or carbon doped silicon oxide film. The oxygen-containing source can be selected from the group consisting of water (H₂O), oxygen (O₂), oxygen plasma, ozone (O₃), NO, N₂O, carbon monoxide (CO), carbon dioxide (CO₂), N₂O plasma, carbon monoxide (CO) plasma, carbon dioxide (CO₂) plasma, and combinations thereof.

In any of the above or in an alternative embodiment, the flowable liquid or oligomer is treated at one or more temperatures ranging from about 100° C. to about 1000° C. to density at least a portion of the materials.

In some embodiments, the post thermal treatment materials are exposed to a plasma, infrared lights, chemical treatment, an electron beam, or UV light to form a dense film. In one embodiment of the invention, a post treatment comprising exposure to UV light exposure is conducted under conditions to emit ethylene and silane gaseous by-products.

The following Examples are provided to illustrate certain embodiments of the invention and shall not limit the scope of the appended claims.

### EXAMPLES

Flowable chemical vapor deposition (FCVD) films were deposited onto medium resistivity (8-12 Ωcm) single crystal silicon wafer substrates and Si pattern wafers. In certain examples, the resultant silicon-containing films or coatings can be exposed to a pre-deposition treatment such as, but not limited to, a plasma treatment, thermal treatment, chemical treatment, ultraviolet light exposure, infrared exposure, electron beam exposure, and/or other treatments to affect one or more properties of the film.

The flowable chemical vapor deposited (FCVD) films were deposited onto medium resistivity (8-12 Ωcm) single crystal silicon wafer substrates and Si pattern wafers. For the pattern wafers, the preferred pattern width is 20˜100 nm with the aspect ratio of 5:1˜20:1. The depositions were performed on a modified FCVD chamber on an Applied Materials Precision 5000 system, using a dual plenum showerhead. The chamber was equipped with direct liquid injection (DLI) delivery capability. The precursors were liquids with delivery temperatures dependent on the precursor's boiling point. To deposit the initial flowable silicon oxide films, typical liquid precursor flow rates ranged from about 100 to about 5000 mg/min, preferably 1000 to 2000 mg/min; the chamber pressure ranged from about 0.75-12 Torr, preferably 0.5 to 2 Torr. Particularly, the remote power was provided by a MKS microwave generator from 0 to 3000 W with the frequency of 2.455 GHz, operating from 2 to 8 Torr. To densify the as-deposit flowable films, the films were thermally annealed and/or UV cured in vacuum using the modified PECVD chamber at 100˜1000 C, preferably 300˜400 C. Thickness and refractive index (RI) at 632 nm were measured by a SCI reflectometer or a Woollam ellipsometer. The typical film thickness ranged from about 10 to about 2000 nm. Bonding properties hydrogen content (Si—H and C—H) of the silicon-based films were measured and analyzed by a Nicolet transmission Fourier transform infrared spectroscopy (FTIR) tool. X-Ray photoelectron spectroscopy (XPS) analyses were performed to determine the elemental composition of the films. A mercury probe was adopted for the electrical properties measurement including dielectric constant, leakage current and breakdown field. The flowability and gap fill effects on an Al patterned wafer were observed by a cross-sectional Scanning Electron Microscopy (SEM) using a Hitachi S-4800 system at a resolution of 2.0 nm.

### Example 1

### Deposition of Flowable Silicon Carbonitride Films Using Triethylsilane (3ES) and Ammonia

Triethylsilane (3ES) was used as a precursor for flowable SiNC film deposition with a remote plasma source (RPS). The 3ES was delivered though the showerhead bypassing the remote microwave. The liquid flow was 2100 mg/min and 200 sccm of helium was added as a carrier gas for the DLI delivery. A mixture of 500 sccm helium and 500 sccm ammonia was flowed through the microwave applicator, while the pressure was 0.2 Torr. The substrate temperature was 40° C. The microwave power was 3000 W. The thickness and refractive index of the as-deposited film were 152 nm and 1.55, respectively. After the thermal anneal the thickness and refractive index were 150 nm and 1.1.54, respectively, indicating little loss of volatile oligomers at elevated temperature. After thermal annealing the films were UV cured for 4 minutes at 400 C, and the thickness and refractive index were 65 nm and 1.54, respectively.

### Example 2

### Deposition of Flowable Silicon Carbonitride Films Using Triethylsilane (3ES) and Ammonia for XPS

Since the flowable films deposited from 3ES and ammonia are unstable in air and will absorb ˜20 atomic % oxygen over time as measured by XPS samples were deposited and then capped in-situ with a standard dense silicon carbon nitride PECVD film deposited using tetramethylsilane and ammonia in order to obtain accurate elemental composition of the films. The 3ES was delivered though the showerhead bypassing the remote microwave. The liquid flow was 2500 mg/min and 200 sccm of helium was added as a carrier gas for the DLI delivery. A mixture of 500 sccm helium and 500 sccm ammonia was flowed through the microwave applicator, and pressure was 0.7 Torr. The substrate temperature was 40° C. The microwave power was 3000 W. The thickness and refractive index of the as-deposited film were 165 nm and 1.53, respectively. The sample was then thermally annealed at 300° C. for 5 minutes and capped with 100 nm of dense SiCN from tetramethylsilane. The elemental composition of the thermally annealed film as measured by XPS is 62% C, 12% C, 25% Si and 1% O. A different sample was deposited under the same conditions, thermally annealed at 300° C. for 5 minutes, UV annealed at 400° C. for 4 minutes and then capped in-situ with 100 nm of dense SiCN using tetramethylsilane. The elemental composition of the films after thermal anneal and UV curing as measured by XPS is 36% C, 20% N, 38% Si and 6% O indicating that there is loss of carbon in the film with UV curing.

### Example 3

### Deposition of Flowable Silicon Carbonitride Films Using Triethylsilane (3ES) and Ammonia for SEM

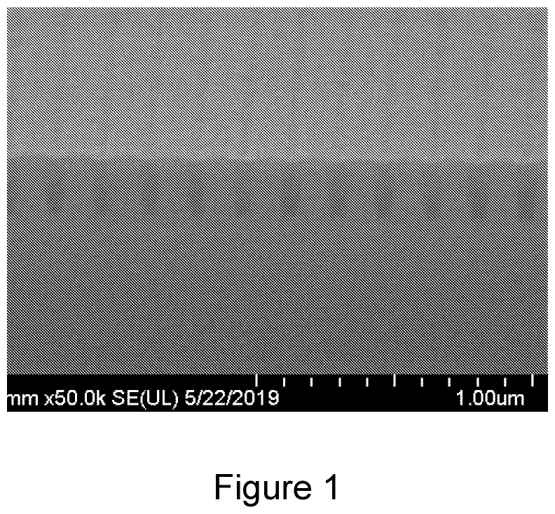

Triethylsilane (3ES) was used for flowable SiNC film deposition with a remote plasma source (RPS). The 3ES was delivered though the showerhead bypassing the remote microwave. The liquid flow was 2500 mg/min and 200 sccm of helium was added as a carrier gas for the DLI delivery. A mixture of 100 sccm helium and 500 sccm ammonia was flowed through the microwave applicator, and pressure was 0.7 Torr. The substrate temperature was 40° C. The microwave power was 2000 W. The as-deposited films were thermally annealed at 300° C. for 5 minutes. The thickness and refractive index of the as-deposited film were 1675.8 nm and 1.431, respectively. After the thermal anneal the thickness and refractive index were 1249.9 nm and 1.423, respectively, indicating the loss of some volatile oligomers at elevated temperature. The elemental composition of the thermally annealed film as measured by XPS was 30.6% C, 40.0% O and 29.4% Si. The dielectric constant of the film after thermal anneal was 3.50 which may be attributed to some moisture absorption due to dangling bonds. After UV cure the thickness and refractive index were 968.3 nmn and 1.349, respectively, indicating that the film was modified by the UV cure and some porosity was introduced. The elemental composition of the films after thermal anneal and UV curing as measured by XPS was 21.6% C, 45.4% O and 33.0% Si indicating that there is loss of carbon in the film with UV curing. The dielectric constant of the UV cured film was 2.56. Cross-sectional SEM indicated that good gap-fill was achieved on patterned wafers. FIG. 1 is a cross-sectional SEM image of the OSG film showing good gap-fill for the thermally annealed samples.

In the examples given as there is no nitrogen in the alkylhydridosilane the nitrogen observed in the deposited films can be expected to derive from the ammonia. Therefore if an oxygen containing activated species were employed it would be expected that the oxygen would be incorporated into the deposited film; alternatively if hydrogen were used as the activated gas it would be anticipated that the deposited film would be composed of silicon carbon with some hydrogen as well.

Although certain principles of the invention have been described above in connection with aspects or embodiments, it is to be clearly understood that this description is made only by way of example and not as a limitation of the scope of the invention.

1. A method for depositing a silicon-containing film in a flowable chemical vapor deposition process, the method comprising:
placing a substrate comprising a surface feature into a reactor which is at one or more temperatures ranging from −20° C. to about 200° C.;
introducing into the reactor a precursor compound having the formula RₙSiH₄₋ₙ wherein R is independently selected from a linear or branched C₂ to C₆ alkyl or a C₆-C₁₀ aryl group and n is a number selected from 1, 2, and 3; and
providing a plasma source into the reactor to at least partially react the compound to form a flowable liquid or oligomer wherein the flowable liquid or oligomer at least partially fills a portion of the surface feature and forms a first film.

2. The method of claim 1 wherein the plasma source in the providing step comprises at least one plasma source selected from the group consisting of nitrogen plasma, a plasma comprising nitrogen and hydrogen, a plasma comprising nitrogen and helium, a plasma comprising nitrogen and argon, ammonia plasma, a plasma comprising ammonia and helium, a plasma comprising ammonia and argon, a plasma comprising ammonia and nitrogen, organic amine plasma, and mixtures thereof.

3. The method of claim 1 wherein the plasma source in the providing step comprises at least one plasma source selected from the group consisting of a carbon source plasma, a hydrocarbon plasma, a plasma comprising hydrocarbon and helium, a plasma comprising hydrocarbon and argon, carbon dioxide plasma, carbon monoxide plasma, a plasma comprising hydrocarbon and hydrogen, a plasma comprising hydrocarbon and a nitrogen source, a plasma comprising hydrocarbon and an oxygen source, and mixtures thereof.

4. The method of claim 1 wherein the plasma source in the providing step comprises at least one plasma source selected from the group consisting of hydrogen plasma, helium plasma, argon plasma, xenon plasma, and mixtures thereof.

5. The method of claim 1 wherein the plasma source in the providing step comprises at least one plasma source selected from the group consisting of water (H₂O) plasma, oxygen plasma, ozone (O₃) plasma, NO plasma, N₂O plasma, carbon monoxide (CO) plasma, carbon dioxide (CO₂) plasma and combinations thereof.

6. The method of claim 1 further comprising performing a thermal treatment at one or more temperatures ranging from about 100° C. to about 1000° C. to densify the first film.

7. The method of claim 6 further comprising exposing the densified first film to at least one further treatment selected from the group consisting of a plasma, infrared light, a chemical treatment, an electron beam, and UV light to further densify the densified first film.

8. The method of claim 1 wherein the plasma source is generated in situ.

9. The method of claim 1 wherein the plasma source is generated remotely.

10. The method of claim 1 wherein a pressure of the reactor is maintained at 100 torr or less.

11. The method of claim 1 wherein the silicon-containing film is selected from the group consisting of silicon carbide, silicon oxide, carbon doped silicon nitride, carbon doped silicon oxide, and carbon doped silicon oxynitride film.

12. The method of claim 1 where the precursor compound is select from the group consisting of ethylsilane, diethylsilane, triethylsilane, isopropyldimethylsilane, isopropyldiethylsilane, phenyldiethylsilane, and benzyldiethylsilane.

13. The method of claim 1 where the precursor compound is triethylsilane.

14. A chemical precursor for forming a silicon containing film having the formula RₙSiH₄₋ₙ wherein R is independently selected from a linear or branched C₂ to C₆ alkyl or a C₆-C₁₀ aryl group and n is a number selected from 1, 2, 3, wherein any impurities of halide ions or metal ions, selected from the group consisting of Al³⁺ ions, Fe²⁺ ions, Fe³⁺ ions, Ni²⁺ ions, and Cr³⁺ ions, are present at a concentration of less than 5 ppm by weight.

15. A film obtained by the method of claim 1.
